(19) United States
(12) Patent Application Publication
(10) Pub. No.: US 2024/0028884 A1
(43) Pub. Date: Jan. 25, 2024

(54) NEURAL NETWORK SYSTEM WITH NEURONS INCLUDING CHARGE-TRAP TRANSISTORS AND NEURAL INTEGRATORS AND METHODS THEREFOR

(71) Applicant: The Regents of the University of California, Oakland, CA (US)

(72) Inventors: Steven L. MORAN, Los Angeles, CA (US); Subramanian S. IYER, Los Angeles, CA (US); Zhe WAN, Los Angeles, CA (US); Sudhakar PAMARTI, Los Angeles, CA (US)

(73) Assignee: The Regents of the University of California, Oakland, CA (US)

(21) Appl. No.: 18/255,346

(22) PCT Filed: Oct. 4, 2021
(86) PCT No.: PCT/US2021/053422

§ 371 Date: May 31, 2023

Related U.S. Application Data
(60) Provisional application No. 63/120,559, filed on Dec. 2, 2020.

(51) Int. Cl. G06N 3/065; H01L 29/792; H10B 43/00

(52) U.S. Cl. CPC G06N 3/065; H01L 29/792; H10B 43/00

(57) ABSTRACT

Present implementations can include a system with a transistor array including a plurality of charge-trap transistors, the charge-trap transistors being operatively coupled with corresponding input nodes, and a neural integrator including a first integrator node and a second integrator node operatively coupled with the transistor array, and generating an output corresponding to a neuron of a neural network system. Present implementations can include a neural integrator with a first integrator node operatively coupled with a first charge-trap transistor of a transistor array, a second integrator node operatively coupled with a second charge-trap transistor of the transistor array, the second charge-trap transistor being operatively coupled with the first charge-trap transistor, and a capacitor operatively coupled with the first integrator node and the second integrator node, and operable to generate an output based on a first voltage at the first integrator node and a second voltage at the second integrator node.

### CROSS-REFERENCE TO RELATED PATENT APPLICATIONS

This application claims priority to U.S. Provisional Patent Application Ser. No. 63/120,559, entitled “ANALOG NONVOLATILE MEMORY-BASED IN-MEMORY COMPUTING MULTIPLY-AND-ACCUMULATE (MAC) ENGINE,” filed Dec. 2, 2020, the contents of all such applications being hereby incorporated by reference in its entirety and for all purposes as if completely and fully set forth herein.

### STATEMENT REGARDING FEDERALLY SPONSORED RESEARCH OR DEVELOPMENT

This invention was made with government support under Grant Number N660011814040, awarded by the Defense Advanced Research Projects Agency, and under Grant Number HDTRA1-17-0035, awarded by the Defense Threat Reduction Agency. The government has certain rights in the invention.

### TECHNICAL FIELD

The present implementations relate generally to electronic devices, and more particularly to a neural network system with neurons including charge-trap transistors and neural integrators.

### BACKGROUND

Artificial intelligence is increasingly desired to address a broader range of problem domains. Concurrently, increasing numbers and types of artificial intelligence techniques are encountering computational limits in response to limits of computing hardware executing those artificial intelligence techniques. In particular, error rates in artificial intelligence techniques executed on conventional computing hardware can exceed thresholds for producing accurate and consistently accurate output of artificial intelligence analysis. Thus, computing hardware constructed to efficiently and accurately execute artificial intelligence processes is desired.

### SUMMARY

Neural networks are attractive systems related to artificial intelligence, for their superior performance in tasks including image and audio recognition. To expand the application space further into and beyond areas such as these, it is desirable to reduce the cost of computation operations and to enable low-power cognitive devices. Present implementations are directed at least to neural networks and neuromorphic systems based on a crossbar architecture of analog non-volatile memory (NVM) device. Neuromorphic computation can include graph networks into and beyond thousands and millions of nodes that are highly resilient to bit-errors. Neuromorphic architectures can advantageously achieve high-throughput and reliable computation in numerous application areas demanding low error rates. Nevertheless, therefore, we need to test the robustness of such systems on a more. Complex data set and function.

Hardware computing systems in accordance with present implementations can advantageously address computational bottlenecks of Von Neumann-architected processors, and can reduce power consumption as compared to systems involving central processing unit (CPU) and graphics processing unit (GPU) processors, for example. Thus, present implementations can advantageously reduce computation latency and energy consumption significantly. Further advantages of present implementations include a reduced number of devices per cell, a large fanout per input and a simplified instruction structure. Thus, present implementations can increase computational performance and energy efficiency of deep neural networks. Thus improved neural networks can increase the range of application areas and quality of artificial intelligence output, including at least devices and networks of devices associated with the Internet-of-things (IoT). Thus, a technological solution for a neural network system with neurons including charge-trap transistors and neural integrators is provided.

Example implementations can include a system with a transistor array including a plurality of charge-trap transistors, the charge-trap transistors being operatively coupled with corresponding input nodes, and a neural integrator including a first integrator node and a second integrator node operatively coupled with the transistor array, and generating an output corresponding to a neuron of a neural network system.

Example implementations can include a system with a first charge-trap transistor having a first transistor node operatively coupled with a first input node of the input nodes, and a second transistor node operatively coupled with the first integrator node.

Example implementations can include a system with a second charge-trap transistor having a first transistor node operatively coupled with the first input node of the input nodes, a second transistor node operatively coupled with the second integrator node, and a third transistor node operatively coupled with a third transistor node of the first charge-trap transistor.

Example implementations can include a with a third charge-trap transistor having a first transistor node operatively coupled with a second input node of the input nodes, and a second transistor node operatively coupled with the first integrator node.

Example implementations can include a system with a fourth charge-trap transistor having a first transistor node operatively coupled with the second input node of the input nodes, a second transistor node operatively coupled with the second integrator node, and a third transistor node operatively coupled with a third transistor node of the third charge-trap transistor.

Example implementations can include a system where the input nodes include inputs to the neural network system.

Example implementations can include a system where the input nodes are operatively coupled with corresponding gate terminals of the plurality of charge-trap transistors.

Example implementations can include a system where the input nodes are operatively coupled with corresponding drain terminals of the plurality of charge-trap transistors.

Example implementations can include a system with a second plurality of charge-trap transistors operatively coupled with a bias node.

Example implementations can include a system where the bias node includes a bias input to the neural network system.

Example implementations can include a system with a switch operatively coupled with the transistor array and the neural integrator, the switch operable to electrically isolate the transistor array from the neural integrator based on a signal propagation delay through the transistor array.

Example implementations can include a system where the plurality of charge-trap transistors includes a plurality of pairs of charge-trap transistors each operatively coupled with a corresponding ones of the input nodes.

Example implementations can include a system where the neural integrator further includes: a capacitor operable to generate the output corresponding to the neuron based on a first voltage at the first integrator node and a second voltage at the second integrator node, and a first analog amplifier having a first output terminal operatively coupled with a first terminal of the capacitor, and a second output terminal operatively coupled with a second terminal of the capacitor.

Example implementations can include a system where the neural integrator further includes: a first current source operatively coupled with the first integrator node and operable to apply a first current to the first integrator node in accordance with a weight associated with the neuron.

Example implementations can include a system where the neural integrator further includes: a second current source operatively coupled with the second integrator node and operable to apply a second current to the second integrator node in accordance with the weight associated with the neuron.

Example implementations can include a system where the input nodes are operable to receive pulse-width modulated input signals.

Example implementations can include a system where the pulse-width modulated input signals have a variable amplitude.

Example implementations can include a system where the pulse-width modulated input signals have a static amplitude.

Example implementations can include a system where the pulse-width modulated signals include training inputs to the neural network system.

Example implementations can include a system where the transistor array and the neural integrator include one neuron of a plurality of interconnected neurons in the neural network system.

Example implementations can include a transistor array device with a first charge-trap transistor having a first transistor node operatively coupled with a first input node of a plurality of input nodes, and a second transistor node operatively coupled with a first integrator node of a neural integrator, and a second charge-trap transistor having a first transistor node operatively coupled with the first input node of the input nodes, a second transistor node operatively coupled with a second integrator node of the neural integrator, and a third transistor node operatively coupled with a third transistor node of the first charge-trap transistor.

Example implementations can include a device with a third charge-trap transistor having a first transistor node operatively coupled with a second input node of the input nodes, and a second transistor node operatively coupled with the first integrator node.

Example implementations can include a device of claim 21, with a fourth charge-trap transistor having a first transistor node operatively coupled with the second input node of the input nodes, a second transistor node operatively coupled with the second integrator node, and a third transistor node operatively coupled with a third transistor node of the third charge-trap transistor.

Example implementations can include a device with a first switch operatively coupled with the first charge-trap transistor.

Example implementations can include a device where the first switch is operable to electrically isolate the first charge-trap transistor and the second charge-trap transistor from the first integrator node and the second integrator node based on a signal propagation delay through the first charge-trap transistor and the second charge-trap transistor.

Example implementations can include a device with a second switch operatively coupled with the second charge-trap transistor.

Example implementations can include a device where the second switch is operable to electrically isolate the first charge-trap transistor and the second charge-trap transistor from the first integrator node and the second integrator node based on a signal propagation delay through the first charge-trap transistor and the second charge-trap transistor.

Example implementations can include a neural integrator with a first integrator node operatively coupled with a first charge-trap transistor of a transistor array, a second integrator node operatively coupled with a second charge-trap transistor of the transistor array, the second charge-trap transistor being operatively coupled with the first charge-trap transistor, a capacitor operatively coupled with the first integrator node and the second integrator node, and operable to generate an output based on a first voltage at the first integrator node and a second voltage at the second integrator node.

Example implementations can include a neural integrator where the output corresponds to a neuron of a neural network system.

Example implementations can include a neural integrator with a first analog amplifier having a first output terminal operatively coupled with a first terminal of the capacitor, and a second output terminal operatively coupled with a second terminal of the capacitor.

Example implementations can include a method of initializing transistors of a transistor array, by applying one or more first voltage pulses to transistors of the transistor array, and applying one or more second voltage pulses to the transistors, subsequent to the applying the first voltage pulses.

Example implementations can include a method where the applying the first voltage pulses includes: applying the first voltage pulses sequentially to each of the transistors.

Example implementations can include a method where the applying the first voltage pulses includes: applying the first voltage pulses in a square wave having a positive magnitude.

Example implementations can include a method where the applying the first voltage pulses includes: applying the second voltage pulses in a square wave having a second activation period less than a first activation period of the first voltage pulses.

Example implementations can include a method where the applying the second voltage pulses includes: applying the second voltage pulses sequentially to each of the transistors.

Example implementations can include a method where the applying the second voltage pulses includes: applying the first voltage pulses in a square wave having a negative magnitude.

Example implementations can include a method where the applying the first voltage pulses includes applying the first voltage pulses during a first programming period, and the applying the second voltage pulses includes applying the second voltage pulses during a second programming period subsequent to the first programming period.

### BRIEF DESCRIPTION OF THE DRAWINGS

These and other aspects and features of the present implementations will become apparent to those ordinarily skilled in the art upon review of the following description of specific implementations in conjunction with the accompanying figures, wherein:

FIG. 1 illustrates an example system, in accordance with present implementations.

FIG. 2 illustrates a first transistor array, in accordance with present implementations.

FIG. 3 illustrates a second transistor array, in accordance with present implementations.

FIG. 4 illustrates a third transistor array, in accordance with present implementations.

FIG. 5 illustrates a neural integrator, in accordance with present implementations.

FIG. 6 illustrates a waveform diagram of a hardware neuron, in accordance with present implementations.

FIG. 7 illustrates a waveform diagram of a hardware neuron including a bias input, in accordance with present implementations.

FIG. 8 illustrates a waveform diagram of a hardware neuron including input having variable magnitudes, in accordance with present implementations.

FIG. 9 illustrates a waveform diagram to initialize a charge-trap transistor of a hardware neuron, in accordance with present implementations.

FIG. 10 illustrates a neural network structure including a plurality of transistor array and neural integrators in a neural network structure, in accordance with present implementations.

FIG. 11A illustrates a first method of initializing a charge-trap transistor of a hardware neuron, in accordance with present implementations.

FIG. 11B illustrates a second method of initializing a charge-trap transistor of a hardware neuron, in accordance with present implementations.

### DETAILED DESCRIPTION

The present implementations will now be described in detail with reference to the drawings, which are provided as illustrative examples of the implementations so as to enable those skilled in the art to practice the implementations and alternatives apparent to those skilled in the art. Notably, the figures and examples below are not meant to limit the scope of the present implementations to a single implementation, but other implementations are possible by way of interchange of some or all of the described or illustrated elements. Moreover, where certain elements of the present implementations can be partially or fully implemented using known components, only those portions of such known components that are necessary for an understanding of the present implementations will be described, and detailed descriptions of other portions of such known components will be omitted so as not to obscure the present implementations. Implementations described as being implemented in software should not be limited thereto, but can include implementations implemented in hardware, or combinations of software and hardware, and vice-versa, as will be apparent to those skilled in the art, unless otherwise specified herein. In the present specification, an implementation showing a singular component should not be considered limiting; rather, the present disclosure is intended to encompass other implementations including a plurality of the same component, and vice-versa, unless explicitly stated otherwise herein. Moreover, applicants do not intend for any term in the specification or claims to be ascribed an uncommon or special meaning unless explicitly set forth as such. Further, the present implementations encompass present and future known equivalents to the known components referred to herein by way of illustration.

A neuromorphic inference engine of a neural network can include hardware operable to execute a trained neural network. The neural network can include one or more convolutional filters and fully-connected filters. The filters can contain synaptic weights in a matrix w to compute a weighted sum y=wx+b for an input vector x and an optional bias vector b. This operation can be done by the computational hardware at the hardware level, by using the conductance of the analog devices as the synaptic weights, a voltage or a pulse-width modulated signal as input, and an integrator of current to collect current from the analog devices. The bias term b can be hidden in the multiplication by adding the an extra term b′ to the weight matrix, and a dummy term b/b′ to the input vector x, so that:

$$[ w , {b}^{′} ] = [ x , \frac{b}{b ′} ] = wx + b \qquad Eq . ( 1 )$$

Present implementations can include a crossbar architecture using charge trap transistors (CTTs) for the inference engine. As one example, a crossbar architecture can include a transistor array structure where rows connect gates of charge trap transistors in the transistor array, columns connect the drains of the charge trap transistors in the transistor array, and sources grounded. It is to be understood that the crossbar architecture is not limited to the above example. Conductance of the CTTs can be set to various values, and multiplication can be done through Ohm's law (I=G*VD). Thus, input to each of the CTTs can be encoded at least in different voltages, by pulse-width modulation (PWM), or by variable magnitude DC inputs. Present implementations can receive variable magnitude DC inputs and convert the DC current by an analog-to-digital converter (ADC) to a digital signal. The ADC can include an integrator to integrate this signal for some fixed time duration corresponding to operating characteristics of the ADC. On-chip current sensing can be done through an integrating circuit at the end of the source column or drain column, to perform a summation using the Kirchhoff current law. Collected charge can be proportional to collected current and time (for PWM input), and can be stored in a capacitor. The collected charge can then be sensed by at least one of voltage level, or time to discharge the capacitor with a constant current in an architecture is scalable to multi-layer. Thus, the input and output of this inference engine can include voltages or PWM signals and can be concatenated for multi-layer networks. It is to be understood that present implementations can include devices other than CCTs, having corresponding operation or structure to the CTTS described herein.

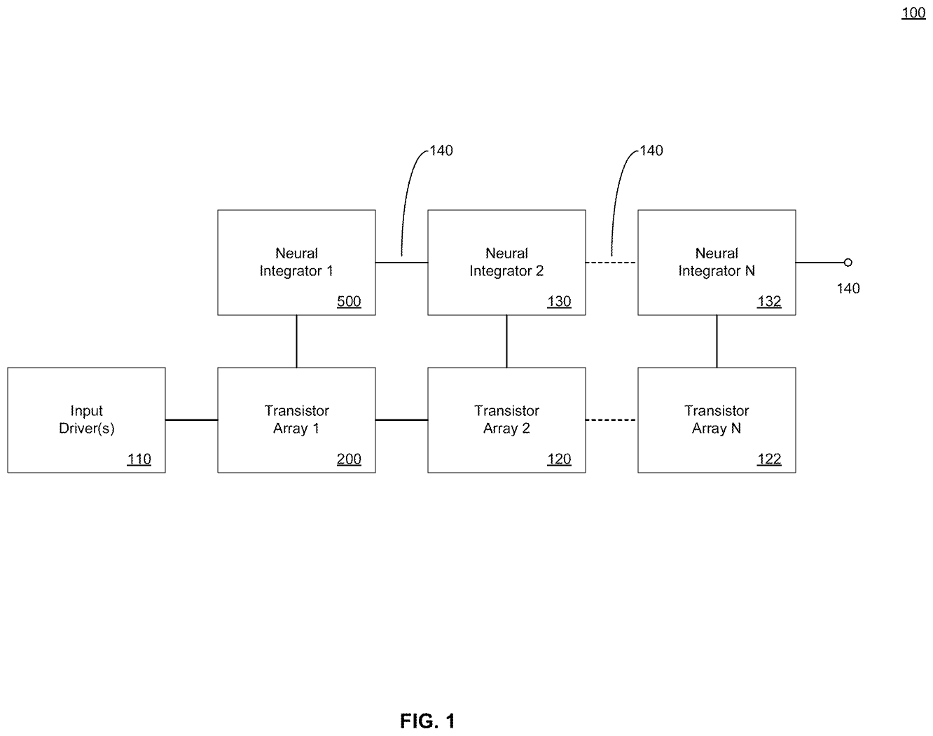

FIG. 1 illustrates an example system, in accordance with present implementations. As illustrated by way of example in FIG. 1, a system 100 can include one or more input drivers 110, one or more transistor arrays 200, 120, and 122, one or more neural integrators 500, 130, and 132, and one or more neuron outputs 140.

The input drivers 110 can include one or more devices to apply one or more inputs to one or more of the transistor arrays 200, 120, and 122. The input drivers 110 can obtain one or more signals each associated with an input to, for example, an input layer or a first layer of a neural network. The input drivers 110 can include at least one electrical wire, lead, trace, or the like associated with each output of the input drivers 110, and can include one or more driver circuits associated with each electrical wire, lead, trace, or the like to provide a signal to one or more of the transistor arrays 200, 120, and 122 compatible with those transistor arrays 200, 120 and 122. The input drivers 110 can include one or more logical or electronic devices including but not limited to integrated circuits, logic gates, flip flops, gate arrays, programmable gate arrays, and the like.

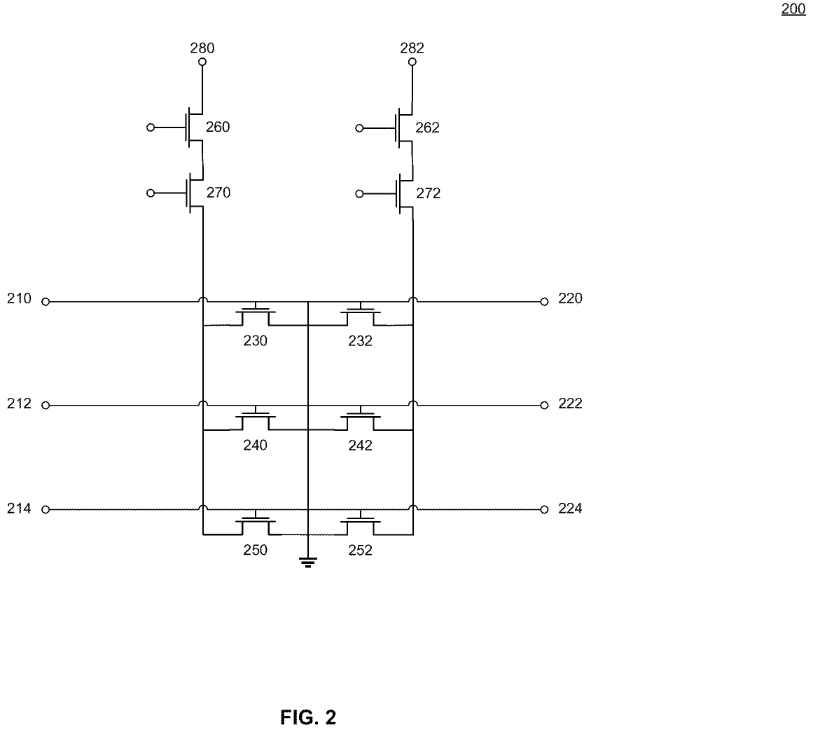

The transistor arrays 200, 120, and 122 can include one or more transistors operatively coupled with each other. For example, the transistor array 120 can include one or more transistors arranged variously operatively coupled with one or more outputs of the input drivers 100. The transistor array 120 can include groups of transistors operatively coupled with individual outputs of the input drivers 110. As one example, the groups of transistor can include pairs of transistors, where each transistor has a corresponding input operatively coupled with an individual corresponding output of the input drivers 110. The transistor array 120 can include any number of transistors, groups of transistors, pairs of transistors, or the like, and can include at least as many transistors, groups of transistors, pairs of transistors, or the like, as number of outputs of the input drivers 110. Thus, the transistor array 120 can receive input from up to all of the inputs associated with an input layer or a first layer of a neural network, or any subset relevant to the neuron with which the transistor array 120 is associated. The transistor arrays 200 and 122 can correspond at least partially in at least one of structure and operation to the transistor array 120. It is to be understood that the number of transistor arrays and the arrangement of the transistor arrays is not limited to the numbers and arrangements illustrated herein by example, and can be modified to accommodate any neural network arrangement of neurons and connections therebetween. As one example, transistors arrays 200, 120 and 130 can be arranged in a cascade arrangement with respect to the input drivers 110. Here, each of the transistors arrays can include at least one electrical wire, lead, trace, or the like arranged in a “crossbar” structure to operatively couple an input of the input drivers 110 to inputs of multiple transistor arrays, by passing the outputs of the inputs drivers 110 through various transistor arrays in series. It is to be further understood that the transistor arrays 200, 120, and 122 can each have varying structures at least in accordance with FIGS. 2, 3 and 4.

The neural integrators 500, 130, and 132 can include one or more devices to generate an output of a neuron. The neural integrators 500, 130, and 132 can obtain input from at least one of the transistor arrays 200, 120 and 130 by being operatively coupled at integrator inputs thereof with a corresponding transistor array. As one example, the neural integrator 130 can generate an output at its corresponding one of the neuron outputs 140, based at least on input received from a transistor array operatively coupled therewith. Thus, the neural integrator 130 can generate an output corresponding to the output of a neuron in a neural network. Further, the neural integrator 130 can be operatively coupled with one or more other neural integrators 500 and 120 to form physical connections between neurons of the neural networks as at least one electrical wire, lead, trace, or the like. The neural integrators 500 and 132 can correspond at least partially in at least one of structure and operation to the neural integrator 130. It is to be understood that the number of neural integrators and the arrangement of the neural integrators is not limited to the numbers and arrangements illustrated herein by example, and can be modified to accommodate any neural network arrangement of neurons and connections therebetween. As one example, neural integrators 500, 130, and 132 can be arranged in a cascade arrangement with respect to the input drivers 110. The neural integrators 500, 130, and 132 can include one or more logical or electronic devices including but not limited to integrated circuits, logic gates, flip flops, gate arrays, programmable gate arrays, and the like.

FIG. 2 illustrates a first transistor array, in accordance with present implementations. As illustrated by way of example in FIG. 2, transistor array 200 can include crossbar inputs 210, 212 and 214, crossbar outputs 220, 222 and 224, computing transistors 230, 232, 240, 242, 250 and 252, a neuron input transistor 260, a neuron output transistor 262, integrator enable transistors 270 and 272, and integrator input nodes 280 and 282. A transistor in accordance with present implementations can include a charge trap transistor (CTT). A CTT can include an n-channel CMOS device with high-κ dielectric whose oxygen vacancies can be used for charge-trapping. As one example, a high-κ dielectric can include HfO₂. A high gate-channel bias can trap charges in the high-κ dielectric which will increase the threshold voltage, and vice versa. As another example, a transistor in accordance with present implementations can include a device having a charge-trapping effect corresponding to a charge trapping effect of the CTT.

The crossbar inputs 210, 212 and 214 can include one or more electrical wires, leads, traces, or the like to operatively couple at least one transistor, group or transistors, or pair of transistors with outputs of the input drivers 110. The crossbar inputs 210, 212 and 214 can operatively couple directly with the outputs of the inputs drivers 110, or can operatively couple with the outputs of the inputs drivers 110 by corresponding crossbar outputs of an external transistor terminal array, resulting in a cascade configuration across transistor arrays. The crossbar outputs 220, 222 and 224 can include one or more electrical wires, leads, traces, or the like to operatively couple at least one transistor, group or transistors, or pair of transistors with corresponding crossbar inputs of an external transistor terminal array, resulting in a cascade configuration across transistor arrays. Each of the crossbar inputs 210, 212 and 214 can include a portion of at least one common electrical wire, lead, trace, or the like shared with a corresponding one of the crossbar outputs 220, 222 and 224. Thus, a system in accordance with present implementations can include a “crossbar” including an electrical wire, lead, trace, or the like, extending through one or more transistor arrays to provide a particular one of the outputs of the input drivers 110 to multiple transistor arrays concurrently or simultaneously.

The computing transistors 230, 232, 240, 242, 250 and 252 can include one or more groups or pairs of transistors operatively coupled with corresponding ones of the crossbar inputs 210, 212 and 214 and the crossbar outputs 220, 222 and 224. The computing transistors 230, 232, 240, 242, 250 and 252 can collectively operate to generate neural processes associated with a neuron of a neural network system. One or more of the computing transistors 230, 232, 240, 242, 250 and 252 can be modified to exhibit a weight associated with a neuron of a neural network system. Specifically, at least one electrical property of the computing transistors 230, 232, 240, 242, 250 and 252 can be modified on an individual transistor basis by a particular programming and erase sequence as discussed herein. The computing transistors 230, 232, 240, 242, 250 and 252 can be operatively coupled with corresponding ones of the crossbar inputs 210, 212 and 214 and the crossbar outputs 220, 222 and 224 by gate terminals thereof, with integrator input nodes at drain terminals thereof, and with a ground terminal at source terminals thereof. Thus, computing transistors 230 and 232 can correspond to a first transistor pair operatively coupled with a first crossbar including the crossbar input 210 and the crossbar output 220, computing transistors 240 and 242 can correspond to a second transistor pair operatively coupled with a second crossbar including the crossbar input 212 and the crossbar output 222, and computing transistors 250 and 252 can correspond to a third transistor pair operatively coupled with a third crossbar including the crossbar input 214 and the crossbar output 224, each receiving one or more neuron inputs from the outputs of the input drivers 110. It is to be understood that the number of computing transistors 230, 232, 240, 242, 250 and 252 and associated devices is not limited to the number shown and can be of an arbitrary number corresponding to the number of inputs for any neural network system. As one example, the number of computing transistors 230, 232, 240, 242, 250 and 252 can be at least in the thousands or millions with respect to a single transistor array. It is to be further understood that the pairs of transistors described herein can also be implemented as single transistors. The single transistor configuration can be programmed with respect to a common reference cell associated with the transistor array or a group of transistor array. As one example, a cell weight greater than a corresponding weight of a reference cell can correspond to a positive weight, and a cell weight less than the corresponding weight of the reference cell can correspond to a negative weight for the cell. As one example, a cell can include any single, pair or group of transistors associated with a crossbar within a transistor array.

It is to be understood that crossbar inputs 210, 212 and 214 can receive at least one input from an external integrator. As one example, one or more of the crossbar inputs 210, 212 and 214 can be operatively coupled with an output of an external integrator associated with a neuron of a different layer than the neuron associated with the crossbar inputs 210, 212 and 214. Here, the crossbar inputs 210, 212 and 214 can be associated with a higher-layer neuron, and can receive input from the output of a lower-level neuron, to create a neuron connection by an electrical wire, lead, trace, or the like. Thus, the system can include multiple crossbars to operatively couple all computing transistors with a particular connection in accordance with a neural network model.

The neuron input transistors 260 and 262 can receive at least one input from an external integrator. As one example, the neuron input transistors 260 and 262 can be operatively coupled with an output of an external integrator associated with a neuron of a different layer than the neuron associated with the neuron input transistors 260 and 262. Here, the neuron input transistors 260 and 262 can be associated with a higher-layer neuron, and can receive input from the output of a lower-level neuron, to create a neuron connection by an electrical wire, lead, trace, or the like.

The integrator enable transistors 260 and 262 can activate and deactivate a connection between at least the transistors of the transistor array 200 and the integrator input nodes 280 and 282 at least in response to a neural network propagation delay. Crossbar inputs 210, 212 and 214 can transmit signal pulses to the computing transistors 230, 232, 240, 242, 250 and 252 of the transistor array 200. These pulses can have non-zero rise and fall times which can contribute error to the weighted sum if pulses that have not reached their maximum or minimum values are propagated through the transistor array 200 and to a neural integrator. The integrator enable transistors 260 and 262 can solve this issue by disconnecting the computing transistors 230, 232, 240, 242, 250 and 252 from its corresponding neural integrator to prevent integration of the current during the ‘precharge’ phase. The integrator enable transistors 260 and 262 can then be turned on quickly to integrate a differential current generated by the transistor array 200, during the integration period only. The integrator protection transistors 270 and 272 can activate and deactivate a connection between at least the transistors of the transistor array 200 and the integrator input nodes 280 and 282 at least in response to an enable signal or the like. The integrator input nodes 280 and 282 can be operatively coupled with a neural integrator to transmit the differential current to the neural integrator, where the integrator enable transistors 260 and 262 and the integrator protection transistors 270 and 272 are activated. It is to be understood that integrator protection transistors 270 and 272 can be optionally included in any transistor array of present implementations.

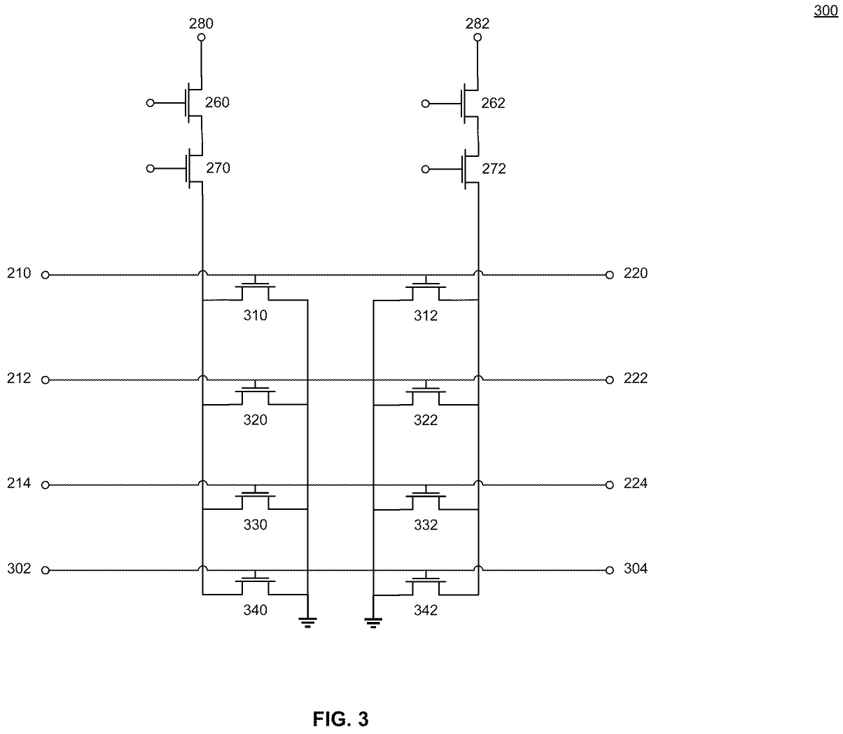

FIG. 3 illustrates a second transistor array, in accordance with present implementations. As illustrated by way of example in FIG. 2, transistor array 300 can include the crossbar inputs 210, 212 and 214, the crossbar outputs 220, 222 and 224, neuron input transistor 260, the neuron output transistor 262, the integrator enable transistors 270 and 272, the integrator input nodes 280 and 282, bias inputs 302 and 304, computing transistors 310, 312, 320, 322, 330 and 332, and bias transistors 340 and 342.

The bias input 302 and bias output 304 can include one or more electrical wires, leads, traces, or the like to operatively couple at least one transistor, group or transistors, or pair of transistors with one or more bias inputs. The bias input 302 and bias output 304 can include one or more outputs of the input drivers 110. The bias input 302 and bias output 304 can include one or more electrical wires, leads, traces, or the like to operatively couple at least one transistor, group or transistors, or pair of transistors with corresponding crossbar inputs of an external transistor terminal array, resulting in a cascade configuration across transistor arrays. Each of the bias input 302 and bias output 304 can include a portion of at least one common electrical wire, lead, trace, or the like shared with a corresponding one of the bias input 302 and bias output 304, similarly to the crossbar discussed herein with respect to crossbar inputs and outputs.

The computing transistors 310, 312, 320, 322, 330 and 332 can include one or more groups or pairs of transistors operatively coupled with corresponding ones of the crossbar inputs 210, 212 and 214 and the crossbar outputs 220, 222 and 224, and can correspond at least partially in one or more of structure and operation to one or more of the computing transistors 230, 232, 240, 242, 250 and 252. The source terminals of computing transistors 310, 320 and 330 can be operatively coupled with a first ground trace or the like, and the source terminals of computing transistors 312, 322 and 332 can be operatively coupled with a second ground trace or the like.

The bias transistors 340 and 342 can include one or more groups or pairs of transistors operatively coupled with bias input 302 and bias output 304, and can correspond at least partially in one or more of structure and operation to one or more of the computing transistors 230, 232, 240, 242, 250 and 252. It is to be understood that the bias transistors can apply a weight to an entire transistor array distinct from a weight associated with any of the computing transistors 310, 312, 320, 322, 330 and 332. It is to be understood that the number of computing transistors 310, 312, 320, 322, 330 and 332, bias transistors 340 and 342, and associated devices is not limited to the number shown and can be of an arbitrary number corresponding to the number of inputs for any neural network system. As one example, the number of computing transistors 310, 312, 320, 322, 330 and 332 and bias transistors 340 and 342 can be at least in the thousands or millions with respect to a single transistor array.

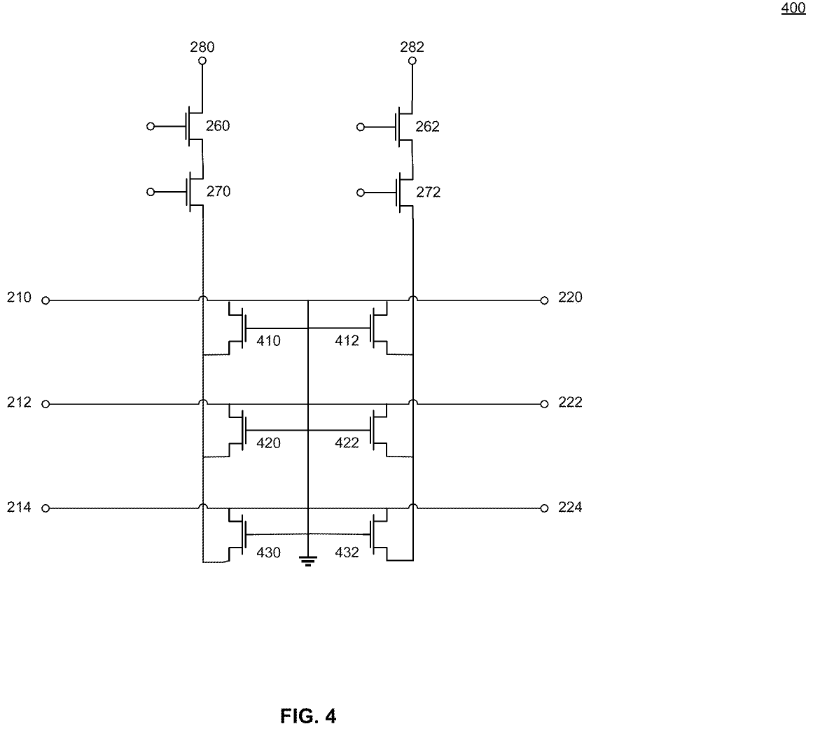

FIG. 4 illustrates a third transistor array, in accordance with present implementations. As illustrated by way of example in FIG. 2, transistor array 400 can include the crossbar inputs 210, 212 and 214, the crossbar outputs 220, 222 and 224, neuron input transistor 260, the neuron output transistor 262, the integrator enable transistors 270 and 272, the integrator input nodes 280 and 282, and computing transistors 410, 412, 420, 422, 430 and 432.

The computing transistors 410, 412, 420, 422, 430 and 432 can include one or more groups or pairs of transistors operatively coupled with corresponding ones of the crossbar inputs 210, 212 and 214 and the crossbar outputs 220, 222 and 224, and can correspond at least partially in one or more of structure and operation to one or more of the computing transistors 230, 232, 240, 242, 250 and 252. The computing transistors 230, 232, 240, 242, 250 and 252 can be operatively coupled with corresponding ones of the crossbar inputs 210, 212 and 214 and the crossbar outputs 220, 222 and 224 by drain terminals thereof, with integrator input nodes at source terminals thereof, and with a ground terminal at gate terminals thereof. Thus, computing transistors 410 and 412 can correspond to a first transistor pair operatively coupled with a first crossbar including the crossbar input 210 and the crossbar output 220, computing transistors 420 and 422 can correspond to a second transistor pair operatively coupled with a second crossbar including the crossbar input 212 and the crossbar output 222, and computing transistors 250 and 252 can correspond to a third transistor pair operatively coupled with a third crossbar including the crossbar input 214 and the crossbar output 224, each receiving one or more neuron inputs from the outputs of the input drivers 110. It is to be understood that the number of computing transistors 410, 412, 420, 422, 430 and 432 and associated devices is not limited to the number shown and can be of an arbitrary number corresponding to the number of inputs for any neural network system. As one example, the number of computing transistors 410, 412, 420, 422, 430 and 432 can be at least in the thousands or millions with respect to a single transistor array.

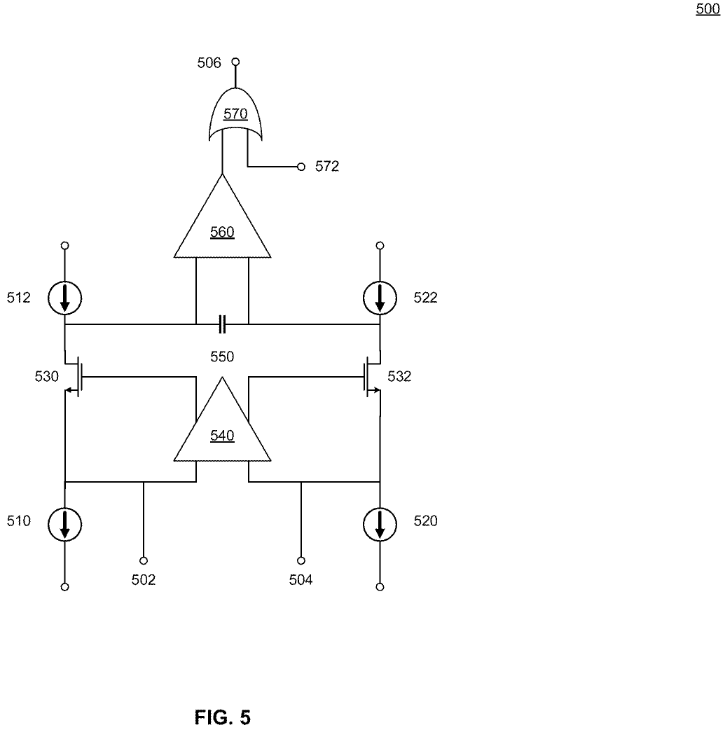

FIG. 5 illustrates a neural integrator, in accordance with present implementations. As illustrated by way of example in FIG. 5, a neural integrator 500 can include integrator inputs 502 and 504, current sources 510, 512, 520 and 522, gain transistors 530 and 532, an integrator device 540, an output capacitor 550, a comparator device 560, an output gate 570, a gate input 572, and a neuron output 506.

The integrator inputs 502 and 504 can be operatively coupled with the integrator input nodes 280 and 282 of any of the transistor arrays 200, 300 and 400, and can receive a differential current based on a difference between currents received at each of the integrator input nodes 280 and 282.

The current sources 510, 512, 520 and 522 can apply current to components of the neural integrator 500. The current sources 510, 512, 520 and 522 can apply various currents to advantageously reduce current mismatches within portions of the neural integrator 500 including mismatches between components of the neural integrator 500 associated with the gain transistor 530 and components of the neural integrator 500 associated with the gain transistor 532. Currents at the current sources 510 and 520 can correspond to a magnitude of I_{B} and Currents at the current sources 510 and 520 can correspond to a magnitude of I_{B}+I_{CM}. Thus, currents at the integrator inputs 502 and 504 can correspond respectively to magnitudes of I_{CM}+I_{DM}/2 and I_{CM}−I_{DM}/2, where I_{B} and I_{CM} can be constant currents and Trim can be a current through the capacitor toward current source 512 and gain transistor 530.

Further, the current sources 510, 512, 520 and 522 can swap various currents to advantageously reduce current mismatches within portions of the neural integrator 500 including mismatches between components of the neural integrator 500 associated with the gain transistor 530 and components of the neural integrator 500 associated with the gain transistor 532. As one example, current sources 510 and 520 can periodically swap the magnitude of currents flowing respectively therethrough, and current sources 512 and 522 can periodically swap the magnitude of currents flowing respectively therethrough. As one example, at a swap frequency of 100 MHz, where a period T=10 ns, the current sources 510, 512, 520 and 522 can swap currents every 1+ cycles. As one example, the current sources 510, 512, 520 and 522 can swap currents at approximately 1% of cycles, at an example swap period of 100 ps per cycle. Mismatch in the neural integrator 500 can result in zero value or inactive value outputs from the neural integrator 500 at a rate that can render the neural integrator 500 inoperable or unreliable for sustained computation as a neuron in a neural network system. If multiple neurons in the neural network system are vulnerable to mismatch, then the neural network system as a whole may experience system failure without mitigation of mismatch within the neural integrator 500. Thus, the current sources 510, 512, 520 and 522 can advantageously increase and maintain reliability of a neural network system implemented including transistor devices. The gain transistors 530 and 532 can apply a gain to the currents of the current sources 510, 512, 520 and 522. Gain transistor 530 can apply a gain to currents associated with the current sources 510 and 512, and gain transistor 532 can apply a gain to currents associated with the current sources 520 and 522.

The integrator device 540 can generate a computational output based on the output of the transistor array with which the neural integrator 500 is operatively coupled at the integrator inputs 502 and 504. The integrator device 540 can include one or more logical or electronic devices including but not limited to amplifiers, integrated circuits, logic gates, flip flops, gate arrays, programmable gate arrays, and the like. The output capacitor 550 can store an electric charge corresponding to a computational result associated with the neuron. The gain transistors 530 and 532 can apply a predetermined gain to the portion of the circuit between the integrator device 540 and the output capacitor 550, to provide a storable physical electrical response corresponding to a computational result associated with the neuron.

The comparator device 560 can generate an output signal waveform corresponding to the stored electrical charge at the capacitor 550. The comparator device 560 can convert the stored charge at the capacitor 550 to a constant-amplitude pulse-width modulated output which can be directly applied as input to the next layer. The comparator device 560 can include one or more logical or electronic devices including but not limited to integrated circuits, logic gates, flip flops, gate arrays, programmable gate arrays, and the like. As one example, the comparator device 560 can implement an ReLU activation function and to produce output waveforms restricted to results with positive charge. The comparator device 560 can also implement a non-linear activation function. An ReLU Linear activation function can produce a constant-amplitude pulse-width modulated output equal in duration to the time for the capacitor 550 to discharge by a constant (DC) current source. It is to be understood that present implementations are not limited to activation functions described herein.

The output gate 570 can receive and output, at the neuron output 506, the output of the comparator device 560 based on a value of the gate input. The output gate 570 can conditionally output the output of the comparator device 560 based on an enable signal, for example, from the gate input 572. The output gate 570 can include an OR gate or physical equivalent thereof, for example. The output gate 570 can include one or more logical or electronic devices including but not limited to integrated circuits, logic gates, flip flops, gate arrays, programmable gate arrays, and the like. The neuron output 506 can include a final computational output of the neuron including the neural integrator 500 and a transistor array. As discussed herein, the neuron output 506 can be provided as input to a higher-level neuron, or can be provided as a neural output of the neural network system in accordance with present implementations.

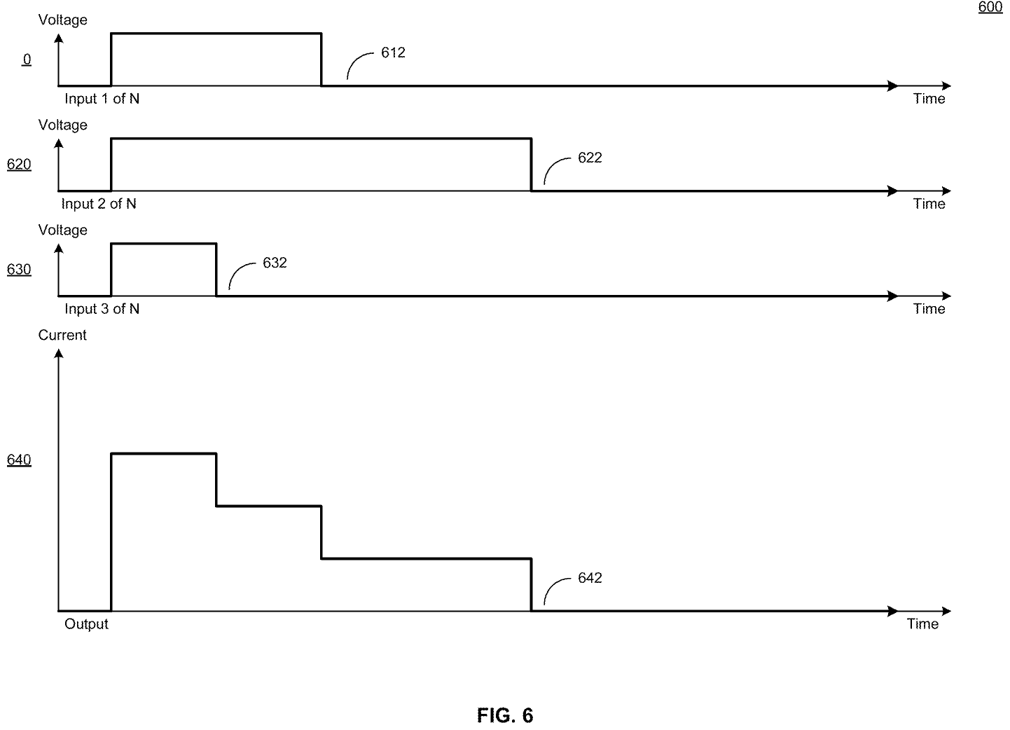

FIG. 6 illustrates a waveform diagram of a hardware neuron, in accordance with present implementations. As illustrated by way of example in FIG. 6, waveform diagram 600 can include a first input window 610 including a first input waveform 612, a second input window 620 including a second input waveform 622, a third input window 630 including a third input waveform 632, and an output window 640 including an output waveform 642.

The first input waveform 612 can correspond to a first pulse-width modulated (PWM) signal having a constant amplitude and a first activation period. The second input waveform 622 can correspond to a second pulse-width modulated (PWM) signal having the constant amplitude and a second activation period longer than the first activation period. The third input waveform 632 can correspond to a third pulse-width modulated (PWM) signal having the constant amplitude and a third activation period shorter than the first activation period and the first activation period.

The output waveform 642 can have a step structure corresponding to a sum of the amplitudes of the input waveforms 612, 622 and 632 at a corresponding time. Thus, in this example, the output waveform 642 can have a first highest amplitude and step down to a zero amplitude. The neural integrator can receive a current corresponding to the output waveform 642 and integrate that current by accumulating charge on an output capacitor of the neural integrator.

Thus, neuron inputs can be encoded as constant-amplitude pulse-width modulated (PWM) inputs, generated using a Digital-to-Time (DTC) counters. As one example, a differential “Twin-Cell” CTT synapse can implement positive and negative weights. Each column of transistors across crossbars can correspond to a weighted sum of the layer's inputs. Each weighted sum can be computed by integrating the differential current over the total duration of all inputs. The adjacent transistor in the row for a crossbar can then convert the accumulated charge to a constant-amplitude PWM output. It is to be understood that a similar approach can also be implemented using single-cell CTT devices.

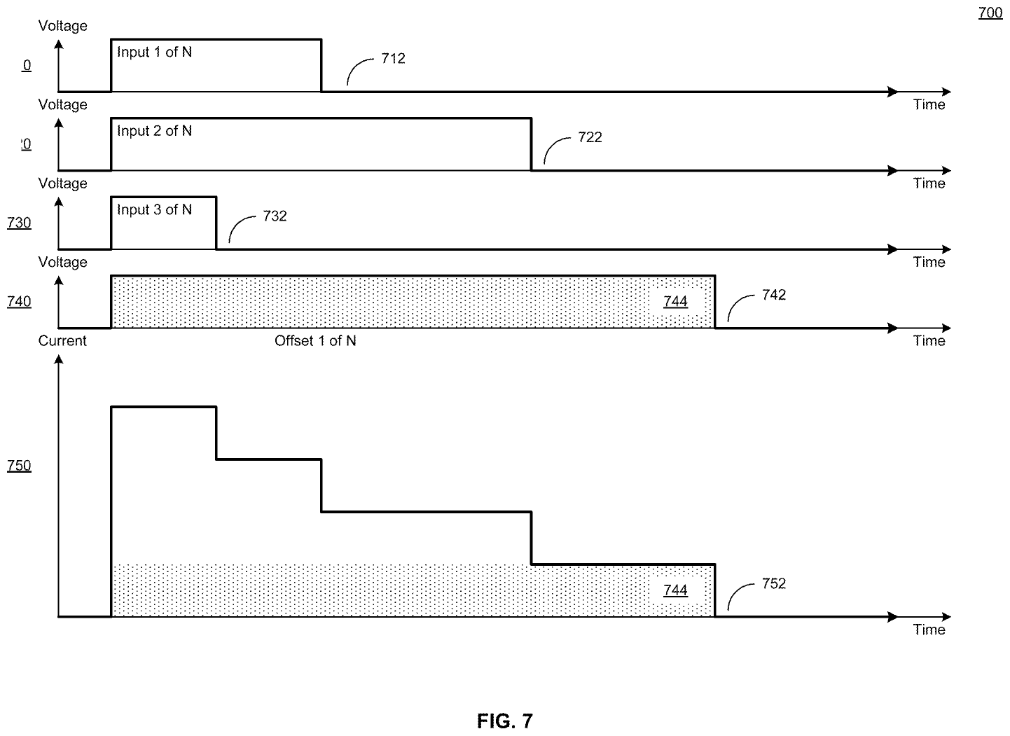

FIG. 7 illustrates a waveform diagram of a hardware neuron including a bias input, in accordance with present implementations. As illustrated by way of example in FIG. 7, waveform diagram 700 can include a first input window 710 including a first input waveform 712, a second input window 720 including a second input waveform 722, a third input window 730 including a third input waveform 732, a fourth input window 740 including a bias input waveform 742 having a bias activation region 744, and an output window 750 including an output waveform 752 and the bias activation region 744. The first input waveform 712, the second input waveform 722, and the third input waveform 732 can respectively correspond at least partially to the first input waveform 612, the second input waveform 622, and the third input waveform 632.

The bias input waveform 742 can correspond to a pulse-width modulated (PWM) signal having a constant amplitude and a particular activation period. The activation period for the bias input waveform 742 to can be longer than the activation period for the input waveforms 712, 722 and 732, to ensure that the bias is constantly and consistently applied through the neuron's computation cycle. The activation period can result in a bias illustrated by the bias activation region 744. In some implementations, one or more weighted-sum or neuron outputs can require a bias term which is a constant value. To implement the bias term, the bias transistors 340 and 342 can be added as discussed herein, and a constant value can be implemented by applying a constant bias term input for every input frame. The output waveform 752 can have a step structure corresponding to a sum of the amplitudes of the input waveforms 712, 722 and 732, and the bias input waveform 742, at a corresponding time. Thus, in this example, the output waveform 752 can have a first highest amplitude and step down to a zero amplitude at a time later than the end of the activation period for the latest input waveform. The neural integrator can receive a current corresponding to the output waveform 752 and integrate that current by accumulating charge on an output capacitor of the neural integrator.

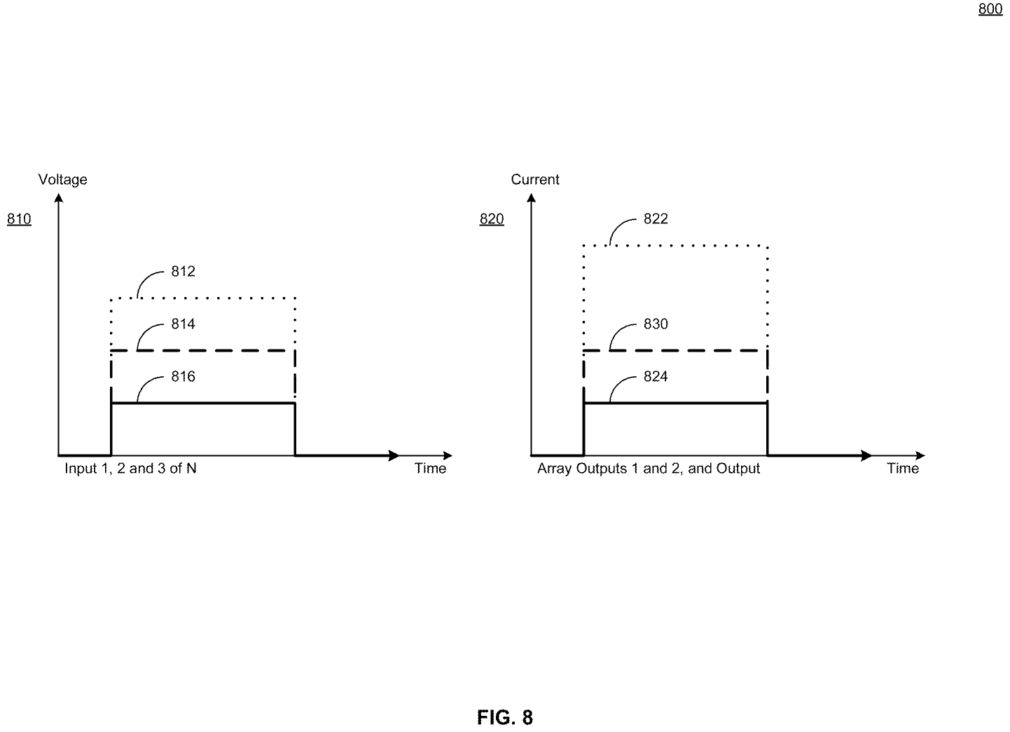

FIG. 8 illustrates a waveform diagram of a hardware neuron including input having variable magnitudes, in accordance with present implementations. As illustrated by way of example in FIG. 8, waveform diagram 810 can include an input window 810 including a first input waveform 812, a second input waveform 814, and a third input waveform 816, and an output window 820 including a first array output 822, a second array output 824, and an output 830.

The first input waveform 812 can correspond to a first pulse-width modulated (PWM) signal having a first amplitude and a constant activation period. The second input waveform 814 can correspond to a second PWM signal having a second amplitude less than the first amplitude, and the constant activation period. The third input waveform 816 can correspond to a third PWM signal having a third amplitude less than the first amplitude and the second amplitude, and the constant activation period.

The first array output 822 can correspond to a first output PWM signal having a first output amplitude greater than the first amplitude of the first input waveform 812, and the constant activation period. The first array output 822 can correspond to a current at the integrator input node 280. The second array output 824 can correspond to a second output PWM signal having a second output amplitude less than the first amplitude of the first input waveform 812 and the second amplitude of the second input waveform 814, and the constant activation period. The second array output 824 can correspond to a current at the integrator input node 282. The output 830 can correspond to a third output PWM signal having a third output amplitude less than the first amplitude of the first input waveform 812 and greater than the second amplitude of the second input waveform 814, and the constant activation period. The third array output 824 can correspond to a differential current between a current at the integrator input node 280 and a current at the integrator input node 282. The neural integrator can receive a current corresponding to the output 830 and integrate that current by accumulating charge on an output capacitor of the neural integrator.

Thus, amplitude-based inputs can be applied to the crossbar inputs 210, 212 and 214 by Digital-to-Analog Converters (DACs) operatively coupled to the crossbar inputs 210, 212 and 214. The DACs can be associated with or integrated into, for example, the input drivers 110. The summed currents can each be measured using an Analog-to-Digital Converters (ADCs) at the output. It is to be understood that the input waveforms 812, 814 and 816 are not limited to a constant or equivalent activation period, and can have distinct activation periods at least as discussed herein with respect to input waveforms 612, 614 and 616.

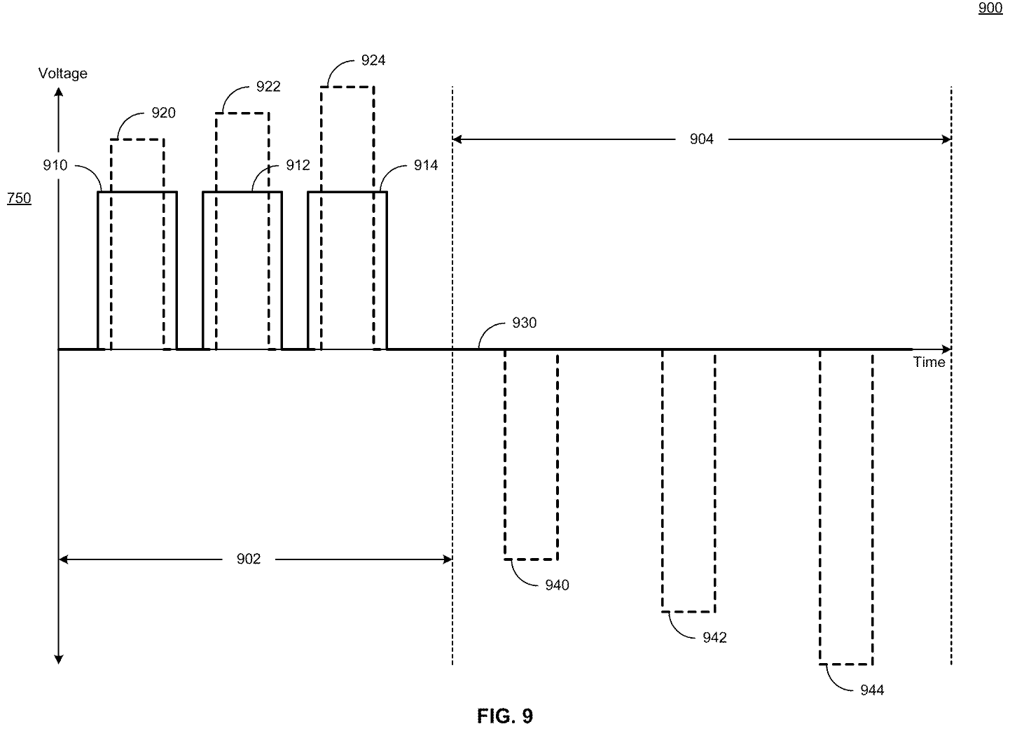

FIG. 9 illustrates a waveform diagram to initialize a charge-trap transistor of a hardware neuron, in accordance with present implementations. As illustrated by way of example in FIG. 9 waveform diagram 900 can include pulses 910, 912 and 914 of a first waveform and pulses 920, 922 and 924 of a second waveform during a programming pulse period 902, and can include a waveform portion 930 of the first waveform and pulses 940, 942 and 944 of the second waveform during an erasure pulse period 904.

CTTs in accordance with present implementations can be hafnium-based high-k CMOS devices. The CTTs can have three initial conditions including unprogrammed, programmed, and erased. The unprogrammed state can correspond to an initial state of a fabricated device before activation or operation. After initial programming of the as-processed device, the multi-time programmable CTT can be cycled between programmed and erased states. An inference current I_{INF} for a particular CTT device can be defined as a drain current at a subthreshold condition to obtain a large dynamic range. Thus, CTTs can achieve a reversible shift of threshold voltage by the programming and erasing process. As one example, a reversible shift of more than 200 mV can be achieved through charge-trapping corresponding to programming, and charge-detrapping corresponding to erasing. A pulsed gate voltage ramp sweep (PVRS) method as discussed herein can advantageously tune I_{INF} to a particular value within its reversible shift range. The pulsed gate voltage ramp sweep (PVRS) method as discussed herein can apply variable and sequential gate bias voltages to various CCTs with short programming pulses. CTTs can thus enhance and exploit properties of the dielectric layers of high-k-metal-gate devices as memory elements. The amount of charge trapped in the HKMG dielectric layer can be determined by the degree of voltage-ramp-stress (VRS). The threshold voltage Shifts in threshold voltage due to the resulting charge trapping can be advantageously sufficient and stable in non-volatile memories. To achieve the programming and erasure cycles, CTTs can be mounted in custom high-speed packages with the source, substrate, n-well, and p-well grounded.

Programming can be accomplished by pulsed-voltage ramped stress by alternating between stressing and sensing voltage pulse. Stressing can include applying high gate voltage V_{G} and drain-voltage V_{D} pulses. Sensing can be performed at lower V_{G} and V_{D} values. The degree of programming can be determined at least partially by the strength of the gate electric field. Retention and stability of the Vth shift can depend at least partially on drain voltage. As one example, V_{D} can be set at 1.2 V, pulse times can be 10 ms, and the peak V_{G} can be set initially at 1.4 V and incremented in magnitude in a series of 39 pulses until reaching a maximum V_{G} of 2.7 V for 22 nm FD SOI devices, and 27 pulses until reaching a maximum of 2.2 V for 14 nm bulk FinFETs. For each sensing pulse, V_{G} is 0.6 V and V_{D} is 0.1 V. The sensing time is 50 ms per cycle.

The pulses 910, 912 and 914 can correspond to V_{DS} voltages during the programming pulse period 902. The pulses 910, 912 and 914 can have a substantially constant amplitude during an active portion of its duty cycle in the programming pulse period 902. As one example, the amplitude can be 1.2 V as discussed above. The pulses 920, 922 and 924 can correspond to V_{GS} voltages during the programming pulse period 902. The pulses 920, 922 and 924 can have a substantially increasing amplitude during an active portion of its duty cycle in the programming pulse period 902. As one example, the amplitude can increase from 1.5 V to 2.7 V as discussed above. The pulses 920, 922 and 924 can be narrower than the pulses 910, 912 and 914, in which pulses 920, 922 and 924 have active portions active for a time period less than an active portion of corresponding pulses of the pulses 910, 912 and 914. The pulses 910, 912 and 914 can each have a rising edge that begins before a corresponding leading edge of the pulses 920, 922 and 924. The pulses 910, 912 and 914 can each have a falling edge that ends after a corresponding falling edge of the pulses 920, 922 and 924.

The waveform portion 930 can correspond to a VDS voltage during the erasure pulse period 904. The waveform portion 930 can have a constant voltage of 0 V. The pulses 940, 942 and 944 can correspond to V_{GS} voltages during the erasure pulse period 904. The pulses 940, 942 and 944 can have a substantially decreasing amplitude during an active portion of its duty cycle in the erasure pulse period 904. As one example, the amplitude can decrease from −1.5 V to −2.7 V. The pulses 940, 942 and 944 can have active portions active for a time period corresponding to active portions of the pulses 920, 922 and 924. It is to be understood that present implementations are not limited to the number of pulses illustrated herein, and can be greater or smaller than the number of pulses illustrated herein.

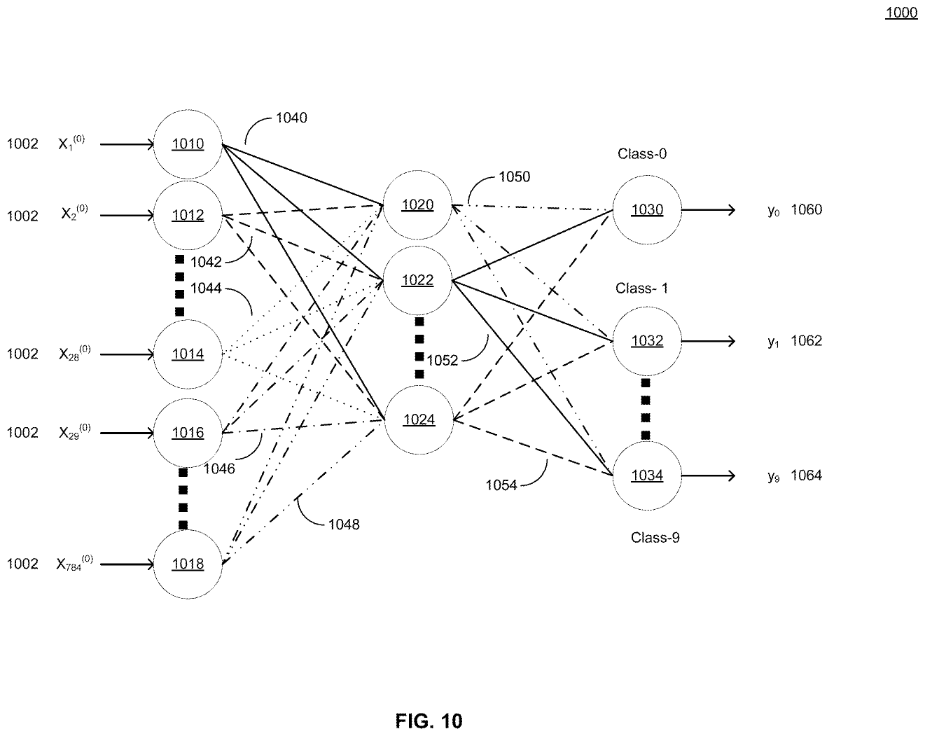

FIG. 10 illustrates an example neural network structure including a plurality of transistor array and neural integrators in a neural network structure, in accordance with present implementations. As illustrated by way of example in FIG. 10, a neural network structure 1000 can include one or more input neurons 1010, 1012, 1014, 1016 and 1018, one or more hidden layer neurons 1020, 1022 and 1024, one or more output neurons 1030, 1032 and 1034, one or more layer connections 1040, 1042, 1044, 1046, 1048, 1050, 1052 and 1054, and one or more neural network outputs 1060, 1062 and 1064. Each of the neurons can correspond to a neural integrator 500 operatively coupled with a transistor array 200, 300 or 400 as discussed herein.

The input neurons 1010, 1012, 1014, 1016 and 1018 can correspond to a first layer or input layer of neurons, receiving inputs 1002 and generating outputs by the layer connections 1040, 1042, 1044, 1046 and 1048. The inputs 1002 can be received from the input drivers 110. The hidden layer neurons 1020, 1022 and 1024 can correspond to a second layer or hidden layer of neurons, receiving the layer connections 1040, 1042, 1044, 1046 and 1048, and generating outputs by the layer connections 1050, 1052 and 1054. The output neurons 1030, 1032 and 1034 can correspond to an output layer of neurons, receiving the layer connections 1050, 1052 and 1054, and generating the neural network outputs 1060, 1062 and 1064. The neural network outputs 1060, 1062 and 1064 can include outputs of a neural network system in accordance with present implementations. The layer connections 1040, 1042, 1044, 1046 1048, 1050, 1052 and 1054 include one or more digital, analog, or like communication channels, lines, traces, or the like. It is to be understood that a neural network system in accordance with present implementations is not limited to the arrangement or numbers of inputs, outputs, neurons, and connections as illustrated herein.

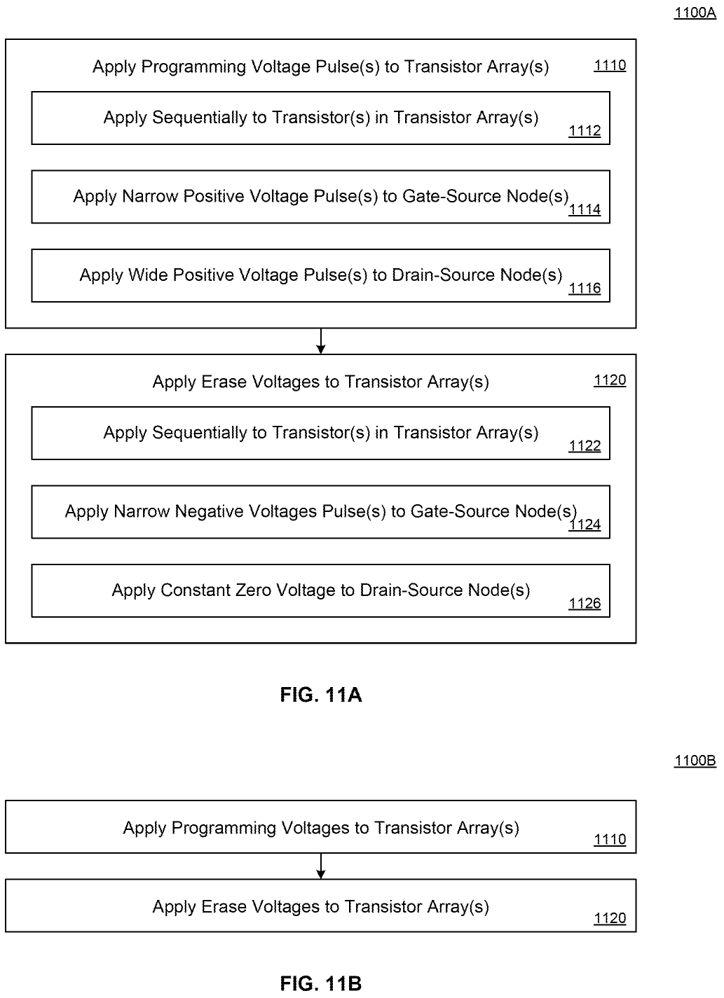

FIG. 11A illustrates a first method of initializing a charge-trap transistor of a hardware neuron, in accordance with present implementations. At least one of the system 100 and the example devices 200, 300 and 400 can perform method 1100A according to present implementations. The method 1100A can begin at step 1110.

At step 1110, the method can apply one or more programming voltage pulses to one or more transistor arrays. Step 1110 can include at least one of steps 1112, 1114 and 1116. At step 1112, the method can apply one or more programming voltages sequentially to transistors in one or more transistor arrays. At step 1114, the method can apply one or more narrow positive voltage pulses to gate and source nodes of one or more transistors of the transistor arrays. At step 1116, the method can apply one or more wide positive voltage pulses to drain and source nodes of one or more transistors of the transistor arrays. The method 1100A can then continue to step 1120.

At step 1120, the method can apply one or more erase voltage pulses to one or more transistor arrays. Step 1120 can include at least one of steps 1122, 1124 and 1126. At step 1122, the method can apply one or more erase voltages sequentially to transistors in one or more transistor arrays. At step 1124, the method can apply one or more narrow negative voltage pulses to gate and source nodes of one or more transistors of the transistor arrays. At step 1126, the method can apply a constant zero voltage to drain and source nodes of one or more transistors of the transistor arrays. The method 1100A can end at step 1120. Present implementations can repeat, cycle, or iterate, for example, method 1100 to verify operation, state, or the like, of one or more of the transistors or transistor arrays. Neurons of present implementations can operate in an on-chip verification (OCV) mode in addition to an inference mode associated with neural network computation. Operation in OCV mode can measure a weight stored, for example, by a by a pair of transistors, group or transistors, single transistor, or the like. Operation in OCV mode can advantageously achieve accurate programming of transistor arrays having weights corresponding to particular neural network structures and computational applications. Thus, method 110 can include repeated, cyclic, or iterating, for example, programming and erase voltage pulses separated by OCV mode verification measurement. The process can stop when a target state is detected. The OCV mode can include a hard-ware linked or user-initiated option to erasing the transistor array or neural network system including one or more transistor arrays. Thus, the OCV can advantageously achieve rapid programming within and of the neural network system according to present implementations.

FIG. 11B illustrates a second method of initializing a charge-trap transistor of a hardware neuron, in accordance with present implementations. At least one of the system 100 and the example devices 200, 300 and 400 can perform method 1100B according to present implementations. The method 1100B can begin at step 1100. At step 1110, the method can apply one or more programming voltage pulses to one or more transistor arrays. Step 1110 of method 100B can correspond at least partially to step 1110 of method 1100A. The method 1100B can then continue to step 1120. At step 1120, the method can apply one or more erase voltage pulses to one or more transistor arrays. Step 1120 of method 100B can correspond at least partially to step 1120 of method 1100A. The method 1100B can end at step 1120.

The herein described subject matter sometimes illustrates different components contained within, or connected with, different other components. It is to be understood that such depicted architectures are illustrative, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality, and any two components capable of being so associated can also be viewed as being “operably couplable,” to each other to achieve the desired functionality. Specific examples of operably couplable include but are not limited to physically mateable and/or physically interacting components and/or wirelessly interactable and/or wirelessly interacting components and/or logically interacting and/or logically interactable components.

With respect to the use of plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.).

Although the figures and description may illustrate a specific order of method steps, the order of such steps may differ from what is depicted and described, unless specified differently above. Also, two or more steps may be performed concurrently or with partial concurrence, unless specified differently above. Such variation may depend, for example, on the software and hardware systems chosen and on designer choice. All such variations are within the scope of the disclosure. Likewise, software implementations of the described methods could be accomplished with standard programming techniques with rule-based logic and other logic to accomplish the various connection steps, processing steps, comparison steps, and decision steps.

It will be further understood by those within the art that if a specific number of an introduced claim recitation is intended, such an intent will be explicitly recited in the claim, and in the absence of such recitation, no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations).

Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general, such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

Further, unless otherwise noted, the use of the words “approximate,” “about,” “around,” “substantially,” etc., mean plus or minus ten percent.

The foregoing description of illustrative implementations has been presented for purposes of illustration and of description. It is not intended to be exhaustive or limiting with respect to the precise form disclosed, and modifications and variations are possible in light of the above teachings or may be acquired from practice of the disclosed implementations. It is intended that the scope of the invention be defined by the claims appended hereto and their equivalents.

1. A system comprising:
a transistor array including a plurality of charge-trap transistors, the charge-trap transistors being operatively coupled with corresponding input nodes; and
a neural integrator including a first integrator node and a second integrator node operatively coupled with the transistor array, and generating an output corresponding to a neuron of a neural network system.

2. The system of claim 1, the transistor array further comprising:
a first charge-trap transistor having a first transistor node operatively coupled with a first input node of the input nodes, and a second transistor node operatively coupled with the first integrator node.

3. The system of claim 2, the transistor array further comprising:
a second charge-trap transistor having a first transistor node operatively coupled with the first input node of the input nodes, a second transistor node operatively coupled with the second integrator node, and a third transistor node operatively coupled with a third transistor node of the first charge-trap transistor.

4. The system of claim 3, the transistor array further comprising:
a third charge-trap transistor having a first transistor node operatively coupled with a second input node of the input nodes, and a second transistor node operatively coupled with the first integrator node.

5. The system of claim 4, the transistor array further comprising:
a fourth charge-trap transistor having a first transistor node operatively coupled with the second input node of the input nodes, a second transistor node operatively coupled with the second integrator node, and a third transistor node operatively coupled with a third transistor node of the third charge-trap transistor.

6. The system of claim 1, wherein the input nodes comprise inputs to the neural network system.

7. The system of claim 1, wherein the input nodes are operatively coupled with corresponding gate terminals of the plurality of charge-trap transistors.

8. The system of claim 1, wherein the input nodes are operatively coupled with corresponding drain terminals of the plurality of charge-trap transistors.

8. The system of claim 1, the transistor array further comprising:
a second plurality of charge-trap transistors operatively coupled with a bias node.

9. The system of claim 8, wherein the bias node comprises a bias input to the neural network system.

10. The system of claim 1, further comprising:
a switch operatively coupled with the transistor array and the neural integrator, the switch operable to electrically isolate the transistor array from the neural integrator based on a signal propagation delay through the transistor array.

11. The system of claim 1, wherein the plurality of charge-trap transistors comprises a plurality of pairs of charge-trap transistors each operatively coupled with a corresponding ones of the input nodes.

12. The system of claim 1, wherein the neural integrator further comprises:
a capacitor operable to generate the output corresponding to the neuron based on a first voltage at the first integrator node and a second voltage at the second integrator node; and
a first analog amplifier having a first output terminal operatively coupled with a first terminal of the capacitor, and a second output terminal operatively coupled with a second terminal of the capacitor.

13. The system of claim 1, wherein the neural integrator further comprises:
a first current source operatively coupled with the first integrator node and operable to apply a first current to the first integrator node in accordance with a weight associated with the neuron.

14. The system of claim 13, wherein the neural integrator further comprises:
a second current source operatively coupled with the second integrator node and operable to apply a second current to the second integrator node in accordance with the weight associated with the neuron.

15. The system of claim 1, wherein the input nodes are operable to receive pulse-width modulated input signals.

16. The system of claim 15, wherein the pulse-width modulated input signals have a variable amplitude.

17. The system of claim 15, wherein the pulse-width modulated input signals have a static amplitude.

18. The system of claim 1, wherein the pulse-width modulated signals comprise training inputs to the neural network system.

19. The system of claim 1, wherein the transistor array and the neural integrator comprise one neuron of a plurality of interconnected neurons in the neural network system.

20. A transistor array device comprising:
a first charge-trap transistor having a first transistor node operatively coupled with a first input node of a plurality of input nodes, and a second transistor node operatively coupled with a first integrator node of a neural integrator; and
a second charge-trap transistor having a first transistor node operatively coupled with the first input node of the input nodes, a second transistor node operatively coupled with a second integrator node of the neural integrator, and a third transistor node operatively coupled with a third transistor node of the first charge-trap transistor.

21. The device of claim 20, further comprising:
a third charge-trap transistor having a first transistor node operatively coupled with a second input node of the input nodes, and a second transistor node operatively coupled with the first integrator node.

22. The device of claim 21, further comprising:
a fourth charge-trap transistor having a first transistor node operatively coupled with the second input node of the input nodes, a second transistor node operatively coupled with the second integrator node, and a third transistor node operatively coupled with a third transistor node of the third charge-trap transistor.

23. The device of claim 20, further comprising:
a first switch operatively coupled with the first charge-trap transistor.

24. The device of claim 23, wherein the first switch is operable to electrically isolate the first charge-trap transistor and the second charge-trap transistor from the first integrator node and the second integrator node based on a signal propagation delay through the first charge-trap transistor and the second charge-trap transistor.

25. The device of claim 23, further comprising:
a second switch operatively coupled with the second charge-trap transistor.

26. The device of claim 25, wherein the second switch is operable to electrically isolate the first charge-trap transistor and the second charge-trap transistor from the first integrator node and the second integrator node based on a signal propagation delay through the first charge-trap transistor and the second charge-trap transistor.

27. A neural integrator, comprising:
a first integrator node operatively coupled with a first charge-trap transistor of a transistor array;
a second integrator node operatively coupled with a second charge-trap transistor of the transistor array, the second charge-trap transistor being operatively coupled with the first charge-trap transistor; and
a capacitor operatively coupled with the first integrator node and the second integrator node, and operable to generate an output based on a first voltage at the first integrator node and a second voltage at the second integrator node.

28. The neural integrator of claim 27, wherein the output corresponds to a neuron of a neural network system.

29. The neural integrator of claim 27, further comprising:
a first analog amplifier having a first output terminal operatively coupled with a first terminal of the capacitor, and a second output terminal operatively coupled with a second terminal of the capacitor.

30. A method of initializing transistors of a transistor array, the method comprising:
applying one or more first voltage pulses to transistors of the transistor array; and
applying one or more second voltage pulses to the transistors, subsequent to the applying the first voltage pulses.

31. The method of claim 30, wherein the applying the first voltage pulses comprises:
applying the first voltage pulses sequentially to each of the transistors.

32. The method of claim 30, wherein the applying the first voltage pulses comprises:
applying the first voltage pulses in a square wave having a positive magnitude.

33. The method of claim 32, wherein the applying the first voltage pulses comprises:
applying the second voltage pulses in a square wave having a second activation period less than a first activation period of the first voltage pulses.

34. The method of claim 30, wherein the applying the second voltage pulses comprises:
applying the second voltage pulses sequentially to each of the transistors.

35. The method of claim 30, wherein the applying the second voltage pulses comprises:
applying the first voltage pulses in a square wave having a negative magnitude.

36. The method of claim 32, wherein the applying the first voltage pulses comprises applying the first voltage pulses during a first programming period, and the applying the second voltage pulses comprises applying the second voltage pulses during a second programming period subsequent to the first programming period.

37. The method of claim 30, wherein the applying the first voltage pulses comprises applying the first voltage pulses within a reversible shift range associated with the transistors.

38. The method of claim 30, wherein the applying the second voltage pulses comprises applying the second voltage pulses within a reversible shift range associated with the transistors.

39. The method of claim 30, wherein the applying the first voltage pulses comprises applying the first voltage pulses satisfying a subthreshold condition associated with the transistors.

40. The method of claim 30, wherein the applying the second voltage pulses comprises applying the second voltage pulses satisfying a subthreshold condition associated with the transistors.
